(19) United States
(12) Patent Application Publication
(10) Pub. No.: US 2026/0036932 A1
(43) Pub. Date: Feb. 5, 2026

(54) IMAGE FORMING APPARATUS USING MOTOR AND HEATER

(71) Applicant: CANON KABUSHIKI KAISHA, Tokyo (JP)

(72) Inventors: YUSUKE NAKASHIMA, Kanagawa (JP); YUUTAROU TAKAENOKI, Kanagawa (JP)

(21) Appl. No.: 19/280,368

(22) Filed: Jul. 25, 2025

(30) Foreign Application Priority Data
Jul. 30, 2024 (JP) 2024-123432

(51) Int. Cl. G03G 15/00; G01R 31/42; G03G 15/20; H02H 7/08

(52) U.S. Cl. CPC G03G 15/5004; G03G 15/2039; G03G 15/2064; G03G 15/80; H02H 7/08; G01R 31/42; G03G 2215/2035

(57) ABSTRACT

A switch is disposed between an external power source and a heater and adjusts power supplied to the heater so that a temperature of the heater approaches a target temperature. A cutoff element is connected in series with the switch between the external power source and the heater and cuts off an alternating current supplied from the external power source to the heater. In a case where an end condition where the heating of the heater is ended is satisfied, the switch stops supplying of the power to the heater. In a case where the abnormal waveform is not detected when the end condition is satisfied, the motor is stopped. In a case where the abnormal waveform is detected when the end condition is satisfied, the motor is stopped after being delayed from the heater.

### BACKGROUND

### Field of the Technology

The present disclosure relates to an image forming apparatus using a motor and a heater.

### Description of the Related Art

In an electrophotographic type fixing device, a heater is heated by an alternating current supplied from a commercial alternating current power source, and fixes toner on a sheet by the heater. When the fixing device continuously heats a sheet having a small size, the temperature of the end portion of the fixing device excessively increases. Therefore, when the temperature of the heater exceeds the temperature threshold, the supply of electric power to the heater is cut off, and the fixing device is protected. Incidentally, when the waveform of the alternating current becomes an abnormal waveform, even if the gate signal of a triac for supplying the current to the heater is switched from the on signal to the off signal, the triac may continue on (commutation failure). In this case, the temperature of the heater increases more than expected. In Japanese Patent Laid-Open No. 2016-136175, it has been proposed to decrease a temperature threshold during a period of time when abnormal waveforms are occurring.

When the temperature threshold is lowered as in Japanese Patent Laid-Open No. 2016-136175, the temperature of the heater tends to exceed the temperature threshold, and the frequency of warning to the user is increased. This can give the user excessive anxiety. In addition, printing may be performed in a printing mode in which the target temperature of the heater is high. In this case, in order to decrease erroneous detection of excessive temperature increase, the rotation speed of a pressurizing member needs to be decreased, and thus the productivity of the image forming apparatus is lowered.

### SUMMARY

The present disclosure provides an image forming apparatus comprising: a first rotating body driven by a motor and configured to rotate; a second rotating body disposed opposite to the first rotating body and configured to cooperate with the first rotating body to form a nip portion; a heater configured to heat the second rotating body by being supplied with an alternating current from an external power source; a switch disposed between the external power source and the heater, and configured to adjust power supplied to the heater so that a temperature of the heater approaches a target temperature; a cutoff element connected in series with the switch between the external power source and the heater and configured to cut off an alternating current supplied from the external power source to the heater; and a waveform sensor configured to detect an abnormal waveform of the alternating current, wherein, in a case where an end condition where the heating of the heater is ended is satisfied, the switch stops supplying of the power to the heater, in a case where the abnormal waveform is not detected when the end condition is satisfied, the motor is stopped, and in a case where the abnormal waveform is detected when the end condition is satisfied, the motor is stopped after being delayed from the heater.

Features of the present disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a cross-sectional view illustrating an image forming apparatus.

FIG. 2 is a cross-sectional view illustrating a fixing device.

FIG. 3 is a circuit diagram illustrating a heater driving circuit.

FIG. 4 is a circuit diagram illustrating a detection circuit for detecting zero-cross.

FIGS. 5A and 5B are drawings illustrating a waveform of an alternating current and a waveform of a zero-cross signal.

FIG. 6 is a diagram for explaining functions realized a CPU.

FIG. 7 is a flowchart illustrating a control method.

FIG. 8 is a circuit diagram illustrating another detection circuit.

FIGS. 9A and 9B are drawings illustrating a waveform of an alternating current and a waveform of a zero-cross signal.

FIG. 10 is a flowchart illustrating a control method.

FIG. 11 is a flowchart illustrating a control method.

FIG. 12 is a flowchart illustrating a control method.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

### 1. Image Forming Apparatus

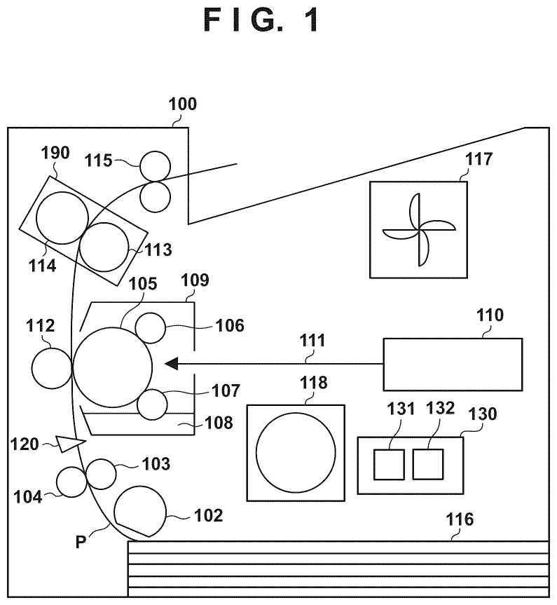

An image forming apparatus 100 shown in FIG. 1 is an electrophotographic type printer. A sheet cassette 116 is a storage for storing and holding a large number of sheets P. A feed roller 102 is driven by a motor 118 to rotate, and feeds the sheet P from the sheet cassette 116 to a conveyance path. Conveyance rollers 103 and 104 provided on the downstream side of the feed roller 102 in a conveyance direction of the sheet P convey the sheet P further downstream. A sheet sensor 120 detects the arrival and passage of the sheet P. The image forming apparatus 100 uses a timing at which a leading edge of the sheet P is detected as a starting timing of an electrophotographic process.

A process cartridge 109 includes a photosensitive drum 105, a charging roller 106, a developing roller 107, and a toner container 108. The photosensitive drum 105 is an image carrier that is driven and rotated by the motor 118. The charging roller 106 uniformly charges a surface of the photosensitive drum 105. A scanning optical device 110 irradiates the surface of the photosensitive drum 105 with light 111 corresponding to image data to form an electrostatic latent image. The developing roller 107 develops an electrostatic latent image using the toner contained in the toner container 108 to form a toner image. A transfer roller 112 transfers the toner image from the photosensitive drum 105 to the sheet P.

A fixing device 190 is disposed downstream of the transfer roller 112. The fixing device 190 includes a heating device 113 and a pressurizing device 114. The heating device 113 heats the sheet P and the toner image. The pressurizing device 114 presses the sheet P and the toner image. Accordingly, the toner image is fixed on the sheet P. A discharge roller 115 is disposed downstream of the fixing device 190. The discharge roller 115 discharges the sheet P to the outside of the image forming apparatus 100.

The fan 117 is a cooling device for decreasing the temperature in the image forming apparatus 100. As the heating device 113 generates heat, the temperature in the image forming apparatus 100 increases. When the internal temperature becomes too high, the toner in the toner container 108 is stuck. The operation of the fan 117 suppresses the sticking of the toner. Further, heat generation of electrical components such as a power supply device is suppressed. The motor 118 is a driving source that applies a driving force to a plurality of rotating bodies (such as the developing roller 107) including the pressurizing device 114. That is, the pressurizing device 114 and the process cartridge 109 are driven by the same driving source. Although only one motor 118 is shown here, a plurality of motors 118 may be employed.

A control board 130 includes a CPU 131, a heater driving circuit 132, or the like. The CPU 131 controls the heater driving circuit 132 to control the temperature of the heating device 113. The CPU 131 also controls the motor 118.

### 2. Heating Device and Pressurizing Device

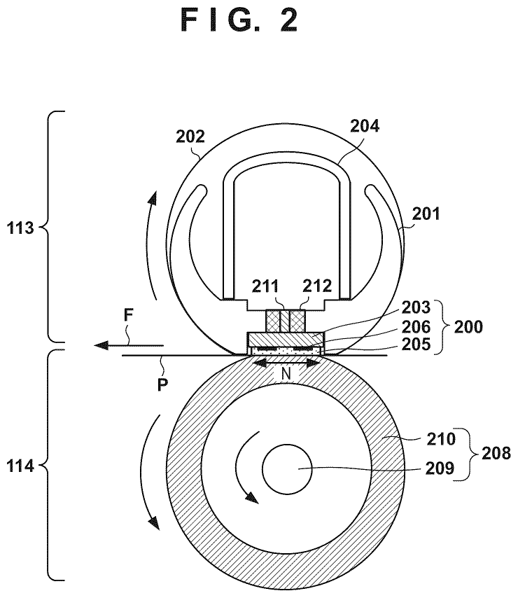

FIG. 2 shows the structure of the heating device 113 and the structure of the pressurizing device 114. The sheet P is conveyed along a conveyance direction F. The heating device 113 includes a heating film 202 and a heater 200. The heating film 202 is a cylindrical rotating body. The heater 200 is a heating body in contact with the inner surface of the heating film 202. The material of a base layer of the heating film 202 is a heat-resistant resin such as polyimide or a metal such as stainless steel.

The pressurizing device 114 includes a pressure roller 208. The pressure roller 208 is disposed to face the heating film 202. The pressure roller 208 cooperates with the heating film 202 and the heater 200 to form a fixing nip portion N.

The heater 200 is held by a heater support member 201 made of a heat-resistant resin. The heater support member 201 also has a guiding function of guiding the rotation of the heating film 202.

A metal stay 204 is a metal stay for applying a pressure from a spring (not shown) to the heater support member 201. The metal stay 204 has a U-shaped cross-section. The metal stay 204 is a member extending parallel to an axial direction of a core metal 209. The metal stay 204 increases the bending rigidity of the heating device 113 and positions the heater support member 201.

The heater 200 includes a heater substrate 203, a heating element 206, and a surface protection layer 205. The heater substrate 203 is, for example, a ceramic substrate. The heating element 206 is a resistance heating element arranged along the substrate longitudinal direction on the heater substrate 203. The surface protection layer 205 is an insulating member (e.g., glass) that covers the heating element 206.

A thermistor 211 and a thermostat 212 are disposed on an upper surface of the heater 200. The thermistor 211 is a temperature sensor (temperature detection element) that detects a temperature correlated with the temperature of the heater 200. The thermostat 212 is a protection element that cuts off the power supply line to the heater 200 when the temperature of the heater 200 becomes an abnormally high temperature. The thermostat 212 may have a thermoswitch or a thermal fuse. The thermistor 211 and the thermostat 212 may be pressed against the heater 200 by a leaf spring (not shown) or the like.

The pressure roller 208 includes the core metal 209 and an elastic layer 210. A material of the core metal 209 is a metal (e.g., iron, aluminum, or the like). A material of the elastic layer 210 is silicone rubber or the like. The pressure roller 208 rotates in the arrow direction by receiving power from the motor 118 via a gear (not shown) connected to the core metal 209 of the pressure roller 208. When the pressure roller 208 rotates, the heating film 202 is driven to rotate with respect to the pressure roller 208 (driving state). When power is not transmitted from the motor 118, the pressure roller 208 is stopped (stopped state). The sheet P carrying the unfixed toner image is conveyed while being sandwiched between the heating film 202 and the pressure roller 208 at the fixing nip portion N. Accordingly, the toner image is fixed on the sheet P.

### 3. Heater Driving Circuit

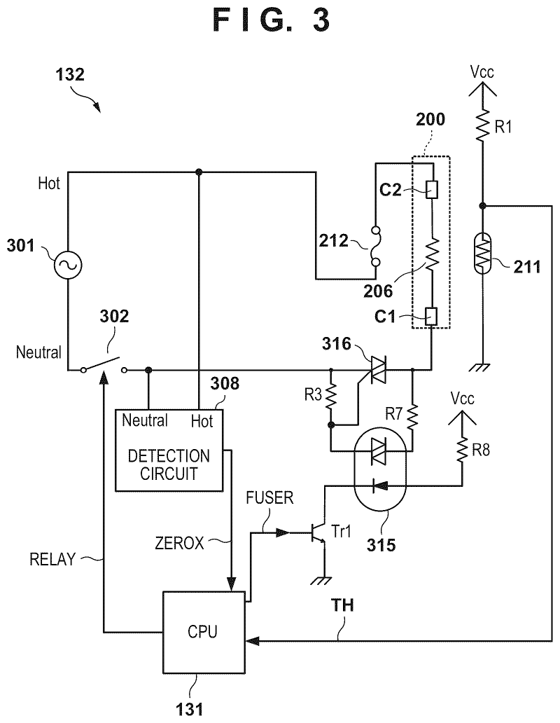

FIG. 3 shows a heater driving circuit 132. An external power source 301 is an alternating current power source connected to the image forming apparatus 100. The external power source 301 may be, for example, a commercial alternating current power source. The energization control of the heater 200 is performed by the conduction (ON) and the cutoff (OFF) of a triac 316. The triac 316 is a semiconductor switch disposed between a neutral (NEUTRAL) side of the external power source 301 and contact portions C1, and C2 of the heater 200. The contact portion C1 is electrically conductive to one end of the heating element 206. The contact portion C2 is electrically conductive to the other end of the heating element 206. The hot (HOT) side of the external power source 301 is connected to the contact portion C1, C2 of the heater 200 via the thermostat 212. In this way, the heater 200 is driven by alternating current.

The detection circuit 308 detects a zero-cross of the alternating current supplied from the external power source 301. The detection circuit 308 generates a zero-cross signal “ZEROX” indicating that the alternating voltage is equal to or lower than a certain threshold, and inputs the zero-cross signal ZEROX to the CPU 131.

One of the main terminals of the triac 316 is connected to the neutral side of the external power source 301 and one end of a resistor R3. The other one of the main terminals of the triac 316 is connected to the contact portion C1 and one end of a resistor R7. The gate terminal of the triac 316 is connected to the other end of the resistor R3 and one end of a phototriac (light receiving element) in the phototriac coupler 315. The other end of the phototriac in the phototriac coupler 315 is connected to the other end of a resistor R7. Here, the resistor R3 and the resistor R7 are resistors for driving the triac 316. The phototriac coupler 315 is a semiconductor device for securing a creepage distance between a primary side circuit (alternating current side circuit) and a secondary side circuit (direct current side circuit). The resistor R3 may be omitted. As the CPU 131 causes a light emitting diode (light emitting element) of the phototriac coupler 315 to emit light, the phototriac coupler 315 is turned on, and the triac 316 is turned on. The light emitting diode of the phototriac coupler 315 is turned on and off repeatedly when an alternating current is supplied. A resistor R8 is connected between the power source voltage Vcc and the anode of the light emitting diode of the phototriac coupler 315. The resistor R8 is a limiting resistor for limiting the current flowing through the light emitting diode. A collector of the transistor Tr1 is connected to a cathode of the light emitting diode of the phototriac coupler 315. An emitter of the transistor Tr1 is grounded. A base of the transistor Tr1 is connected to the CPU 131. The CPU 131 turns on/off the phototriac coupler 315 through the transistor Tr1 by outputting the control signal “FUSER” to the base.

One end of the thermistor 211 is connected to the power source voltage Vcc via a resistor R1. The other end of the thermistor 211 is grounded. By dividing the power source voltage Vcc by an internal resistance of the thermistor 211 varying in response to the temperature and a resistance of the resistor R1, a detection signal TH is generated. The detection signal TH is inputted to the CPU 131. The CPU 131 controls the triac 316 such that the detected temperature of the thermistor 211 indicated by the detection signal TH approaches the set temperature (target temperature) of the heater 200. A proportional integral (PI) control may be employed for this control. The CPU 131 calculates power to be supplied to the heater 200, and calculates a phase angle (phase control) or a control level of a wave number (wave number control) corresponding to the power. The CPU 131 controls the triac 316 using the control level with the edges of the zero-cross signal ZEROX as a temporal reference.

A relay 302 is an electromagnetic relay disposed between the external power source 301 and the triac 316 and connected in series to the triac 316. The CPU 131 supplies a relay driving signal “RELAY” to the relay 302 to control the state (cutoff/conductive) of the relay 302. When the relay 302 is switched to the conductive state, the external power source 301 is supplied to the heater 200.

Here, if some trouble occurs, such as a short circuit of the triac 316, the heating device 113 may be in a heat generation state exceeding a steady state assumed in the design (abnormal temperature increase). In this case, the thermostat 212 cuts off the power supply to the heater 200. When the detected temperature of the thermistor 211 indicated by the detection signal TH becomes equal to or higher than a predetermined threshold, CPU 131 switches the relay 302 from the conductive state to the non-conductive state. Accordingly, the power supply to the heater 200 is cutoff. The operating temperature of the thermostat 212 is higher than the temperature threshold of the relay 302.

### 4. Detection of Abnormal Waveform

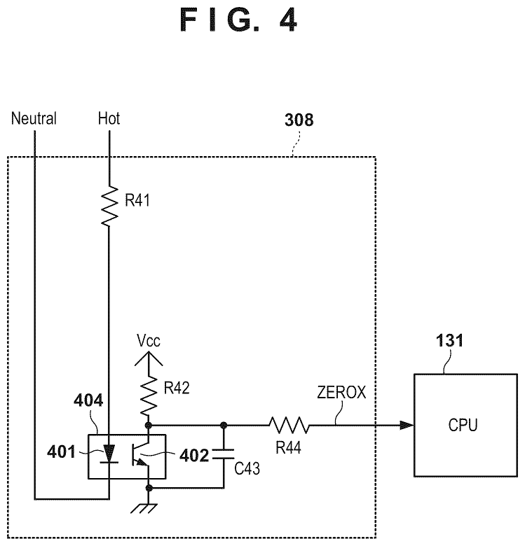

As shown in FIG. 4, the hot side potential of the external power source 301 is connected to the anode of a light emitting diode 401 of a photocoupler 404 via a current limiting resistor R41. The cathode of the light emitting diode 401 is connected to the neutral side of the external power source 301. That is, the light emitting diode 401 is connected in parallel to the external power source 301. The photocoupler 404 is a semiconductor device for securing a creepage distance. A collector of a phototransistor 402 of the photocoupler 404 is connected to the power source voltage Vcc via a resistor R42. The resistor R42 is a current limiting resistor that limits the current flowing through the phototransistor 402. An emitter of the phototransistor 402 is grounded. A capacitor C43 and a resistor R44 form filters for reducing noises. The output signal (zero-cross signal ZEROX) of the photocoupler 404 is inputted to the CPU 131 through the filters. In a less noisy environment, the capacitor C43 and the resistor R44 may be omitted.

In FIG. 4, the hot side of the external power source 301 is connected to an anode of the light emitting diode 401. The neutral side of the external power source 301 is connected to a cathode of the light emitting diode 401. However, this is merely an example. The hot side may be connected to a cathode of the light emitting diode 401, and the neutral side may be connected to the anode.

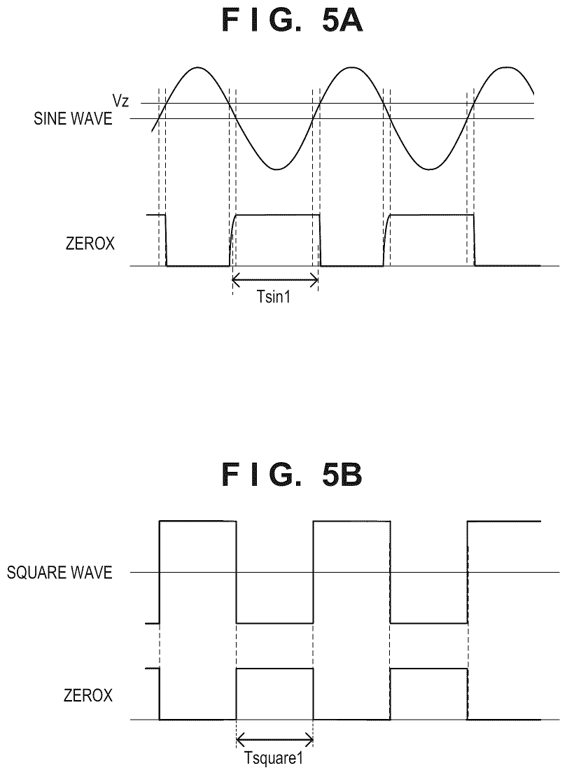

FIG. 5A and FIG. 5B show a relationship between an input waveform from the external power source 301 and a waveform (pulse waveform) of the zero-cross signal ZEROX. The zero-cross signal ZEROX is a pulse signal that repeats rising and falling. As shown in FIG. 5A, the waveform of the alternating current supplied from the external power source 301 is a sine wave (normal case). When the hot side potential is higher than the neutral side potential and a difference between them is higher than a threshold voltage Vz, the photocoupler 404 is turned on. Consequently, the zero-cross signal ZEROX changes from a high level to a low level (falling). The threshold voltage Vz is determined by the resistor R41. The hot-side potential may be lower than the neutral-side potential or the hot-side potential may be lower than the threshold voltage Vz. In this case, the photocoupler 404 is turned off. Consequently, the zero-cross signal ZEROX changes from a low level to a high level (rising). That is, the level of the zero-cross signal ZEROX is switched according to whether the hot-side potential is higher than the neutral-side potential by the threshold voltage Vz or more. Therefore, a pulse waveform having an on-time Tsin1 wider than the on-time determined from the two true zero-cross points is outputted to the CPU 131. Note that the on-time may be referred to as an on-duty or an on-duty width.

As shown in FIG. 5B, the waveform of the alternating current supplied from the external power source 301 is a square wave. A square wave causes a malfunction (commutation phenomenon) of the triac 316 because the voltage change rate at the zero-cross timing is large. Therefore, a square wave is a kind of an abnormal waveform. The on-time of the square wave is the same as the on-time determined from the two true zero-cross points. That is, the on-time of the zero-cross signal ZEROX when the square wave is inputted is Tsquare1, which is equal to the on-time of the square wave. Comparing FIG. 5A with FIG. 5B, it can be seen that Tsquare1 of the square wave (abnormal waveform) is shorter than Tsin1 of the sine wave (normal waveform).

The CPU 131 can monitor the on-time of the zero-cross signal ZEROX to detect an abnormal waveform. For example, the CPU 131 determines whether the on-time Ton of the zero-cross signal ZEROX is less than a threshold (e.g., Tsin1). When Ton is less than Tsin1, the CPU 131 determines that the inputted alternating current waveform is an abnormal waveform. The on-time Tsquare1 of the zero-cross signal ZEROX for the square wave is less than Tsin1. Thus, the CPU 131 can detect a square wave. When Ton is not less than Tsin1, the CPU 131 determines that the inputted alternating current waveform is a normal waveform.

### 5. CPU Functions

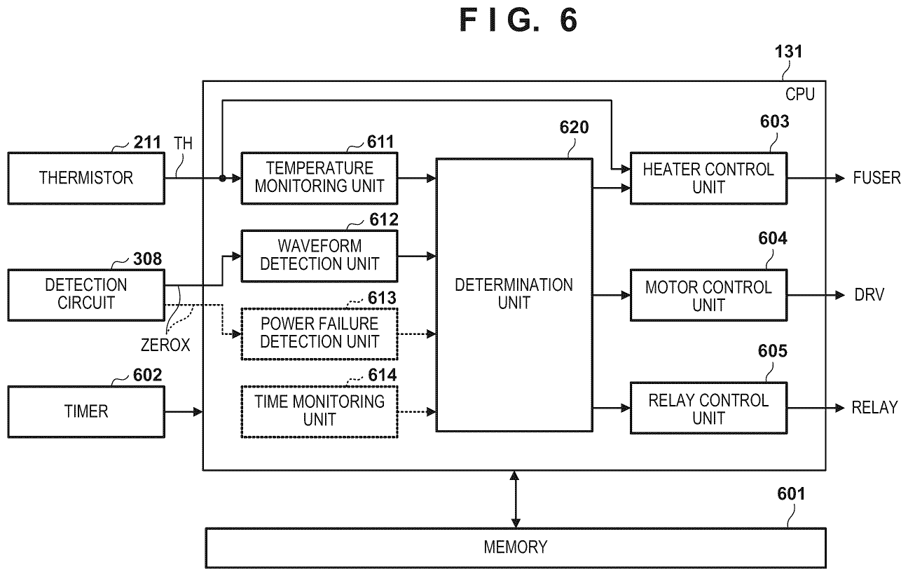

FIG. 6 shows a plurality of functions realized by the CPU 131 executing a control program. A part or all of the functions may be implemented by a hardware circuit such as an application specific integrated circuit (ASIC) or a field-programmable gate array. A memory 601 is a storage device that may include a random access memory (RAM), a read only memory (ROM), a solid state drive (SSD), a hard disk drive (HDD), or the like. A ROM area of the memory 601 stores the control program. A timer 602 is a real time clock or a counter circuit. A heater control unit 603 controls the triac 316 so that the temperature of the heater 200 detected by the thermistor 211 approaches the target temperature. A motor control unit 604 generates a driving signal “DRV” and controls the rotation/stoppage of the motor 118. In addition, the motor control unit 604 can also control the rotation speed of the motor 118. That is, the motor 118 can control the rotation speed of the pressure roller 208. A relay control unit 605 generates the control signal RELAY for controlling ON (conductive state) and OFF (cutoff state) of the relay 302, and supplies the control signal RELAY to the relay 302.

A temperature monitoring unit 611 converts the detection signal TH output from the thermistor 211 into a temperature, acquires a comparison result between the detected temperature and the threshold temperature, and outputs the comparison result to a determination unit 620. A waveform detection unit 612 detects the abnormal waveform of the alternating current based on the zero-cross signal ZEROX. A power failure detection unit 613 is optional, and detects a power failure of the external power source 301 based on the zero-cross signal ZEROX. For example, the power failure detection unit 613 determines that a power failure has occurred when the zero-cross signal ZEROX cannot be detected for a prescribed time. Note that the image forming apparatus 100 has a spare power source (e.g., a battery) capable of supplying power for a predetermined period of time even when the external power source 301 fails. A time monitoring unit 614 is an option and monitors a continuation time of the abnormal waveform and a forced cutoff time of the relay 302.

The determination unit 620 determines whether or not a heating end condition of the heater 200 is satisfied based on print job information (e.g., the number of printed sheets). Further, the determination unit 620 determines whether or not the power supply to the heater 200 should be stopped based on the comparison result (presence or absence of abnormal temperature increase) of the temperature monitoring unit 611. The determination unit 620 determines whether to delay and stop the motor 118 later than the heater 200 based on the detection results of the waveform detection unit 612. For example, the determination unit 620 outputs a stop command to the heater control unit 603 at a first timing when the heating end condition is satisfied. The heater control unit 603 switches the triac 316 from on to off based on the stop command. The determination unit 620 outputs a stop command to the motor control unit 604 at a second timing. The motor control unit 604 stops the motor 118 in accordance with the stop command. The second timing is a timing later than the first timing by a predetermined time. This predetermined time may be referred to as a rotation extension time or a stop extension time.

### 6. Flowchart

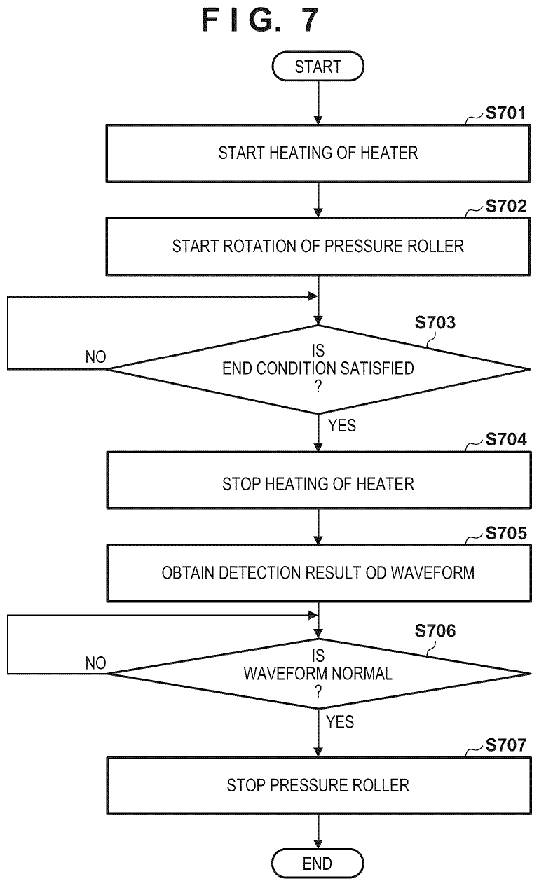

FIG. 7 shows a control method executed by the CPU 131 in accordance with the control program. When a print job is inputted, the CPU 131 executes the following process. The target temperature and the conveyance speed of the heater 200 are determined in accordance with a basis weight of the sheet P designated by the print job.

In the step S701, the CPU 131 (heater control unit 603) starts heating of the heater 200. The heater control unit 603 increases the temperature of the heater 200 to the target temperature and maintains the temperature of the heater 200 at the target temperature.

In the step S702, the CPU 131 (motor control unit 604) starts rotation of the pressure roller 208 by the motor 118. Note that the step S701 and the step S702 may be executed at the same time or the step S702 may be executed prior to the step S701.

In the step S703, the CPU 131 (determination unit 620) determines whether or not the heating-end condition is satisfied. The heating end condition may be, for example, that printing on the number of sheets P designated by the print job information is completed. The heating end condition may be that the temperature of the heater 200 has reached the target temperature. When the heating end condition is satisfied, the CPU 131 advances the process from the step S703 to the step S704.

In the step S704, the CPU 131 (heater control unit 603) changes the heater driving signal FUSER so as to turn off the triac 316, thereby stopping the heating of the heater 200. The motor control unit 604 continues the rotation of the pressure roller 208 by the motor 118.

Note that, if the pressure roller 208 is stopped together with the heater 200, a problem may occur. For example, if the waveform of the alternating current is a square wave, the triac 316 remains on, and the heating of the heater 200 continues. At this time, when the motor 118 stops, a sudden temperature difference occurs between the fixing nip portion N and the other portions. This may cause failure of the heating device 113 and the pressurizing device 114. Therefore, it is necessary to detect an abnormal waveform.

In a period (rotation extension period) during which the driving of the pressure roller 208 is continued, the driving speed (rotation speed) of the pressure roller 208 may be any speed as long as the failure can be suppressed. The rotation speed during the rotation extension period may be different from the rotation speed during the heating process.

In the step S705, the CPU 131 (waveform detection unit 612) acquires the detection result of the waveform of the alternating current based on the zero-cross signal ZEROX. In the waveform detection, for example, the waveform detection unit 612 measures a time “ton” from a timing at which the alternating voltage becomes equal to or lower than the threshold voltage Vz to a timing at which the alternating voltage exceeds the threshold voltage Vz. In this way, the waveform detection may be to measure the time ton. The waveform detection is not required to be performed in the step S705 and may be performed at other times. For example, it may be performed at regular measurement intervals in parallel with the processing shown in FIG. 7. The detection result of the waveform may be stored in a memory provided inside or outside the CPU 131, and may be read out as needed.

In the step S706, the CPU 131 (determination unit 620) determines whether or not the alternating current waveform is normal waveform. If ton is equal to or greater than the threshold (e.g., Tsin1), the waveform of the alternating current is a normal waveform. If ton is less than the thresholds, the waveform of the alternating current is an abnormal waveform. When the detected waveform is a normal waveform, the CPU 131 advances the process from the step S706 to the step S707. If the detected waveform is an abnormal waveform, the CPU 131 waits for the detected waveform to return to the normal waveform.

In the step S707, the CPU 131 (motor control unit 604) stops the rotation of the pressure roller 208 by the motor 118.

According to the first embodiment, when an abnormality occurs in the waveform of the alternating current, the pressurizing device 114 stops after issuing a stop command to the heating device 113 (this is referred to a rotate continuation control or a stop delay control). That is, that the CPU 131 delays the stop timing of the motor 118 from the stop timing of the heater 200. Accordingly, even if the triac 316 is unintentionally turned on by the abnormal waveform, failure of the pressurizing device 114 and the heating device 113 is less likely to occur. This is because the rotation of the pressurizing device 114 continues, and the pressurizing device 114 stops after the temperature difference between the fixing nip portion N and the other portions becomes small.

The motor 118 may be a common driving source for the pressurizing device 114 and the process cartridge 109. In this case, the CPU 131 may then advance the driving stop of the pressurizing device 114 in view of the lifetime of the photosensitive drum 105 or the like. That is, the rotation continuation time of the motor 118 may be shortened. For example, the rotation continuation time may be shortened as the duration of use of the photosensitive drum 105 is increased.

### Second Embodiment

In the second embodiment, a part of the detection circuit 308 of the first embodiment is modified. Specifically, a transistor for improving the responsiveness of the zero-cross signal ZEROX is added between the photocoupler 404 and the CPU 131. Further, a constant voltage element (e.g., a Zener diode) may be added between the hot side of the external power source 301 and the photocoupler 404 or between the neutral side of the external power source 301 and the photocoupler 404. Description of matters common to the first embodiment in the second embodiment will be omitted.

### 1. Detection Circuit of Abnormal Waveform

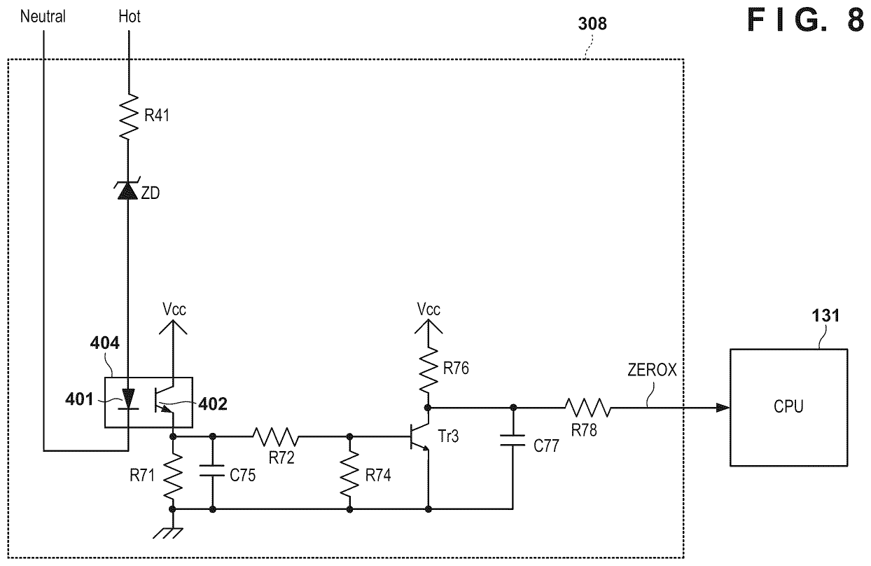

FIG. 8 shows the detection circuit 308 of the second embodiment. On the hot side of the external power source 301, a Zener diode “ZD” is added between the current limiting resistor R41 and the anode of the light emitting diode 401 of the photocoupler 404. This helps to adjust the threshold voltage Vz for detecting abnormal waveforms. Note that both the resistor R41 and the Zener diode ZD may be located between the hot side of the external power source 301 and the photocoupler 404. Both the resistor R41 and the Zener diode ZD may be located between the neutral side of the external power source 301 and the photocoupler 404. Here, the positions of the resistor R41 and the Zener diode ZD, which are connected in series adjacent to each other, can be reversed. Further, the resistor R41 may be between the hot side of the external power source 301 and the photocoupler 404, and the Zener diode ZD may be between the neutral side of the external power source 301 and the photocoupler 404. Further, the Zener diode ZD may be between the hot side of the external power source 301 and the photocoupler 404, and the resistor R41 may be between the neutral side of the external power source 301 and the photocoupler 404.

A resistor R71 is connected between the emitter of the phototransistor 402 of the photocoupler 404 and the ground potential. The resistor R71 is a current limiting resistor that limits the current flowing through the phototransistor 402. Further, the phototransistor 402 is connected to a filter. This filter is a noise-reducing filter formed by a resistor R72 and a capacitor C75. One end of the resistor R72 is connected to the emitter of the phototransistor 402. The other end of the resistor R72 is connected to the base of the transistor Tr3. One end of the capacitor C75 is connected to one end of the resistor R72. The other end of the capacitor C75 is grounded.

A resistor R74 is a resistor connected between a base and an emitter of a transistor Tr3. The resistor R74 is provided to prevent malfunction of the transistor Tr3. A resistor R76 is a current limiting resistor of the transistor Tr3. The resistor R76 is connected between a collector of the transistor Tr3 and the power source voltage Vcc. The zero-cross signal ZEROX outputted from the collectors of the transistors Tr3 is inputted to the CPU 131 via a filter. The filter is formed of a capacitor C77 and a resistor R78 to reduce noises.

In FIG. 8, the anode of the light emitting diode 401 of the photocoupler 404 is connected to the hot side of the external power source 301, and the cathode is connected to the neutral side. However, this is merely an example. The hot side may be connected to a cathode of the light emitting diode 401, and the neutral side may be connected to the anode.

In a less noisy environment, the capacitor C75 and the resistor R72 may be omitted. Similarly, the capacitor C77 and the resistor R78 may be omitted.

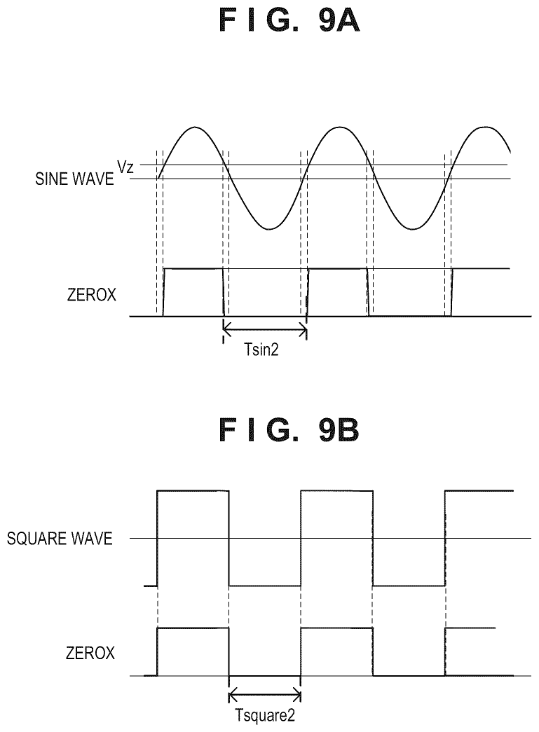

FIG. 9A shows the zero-cross signal ZEROX when the waveform of the alternating current is normal (sine wave). Note that the waveform of the zero-cross signal ZEROX of the second embodiment is inverted as compared with the waveform of the zero-cross signal ZEROX of the first embodiment. This is due to the addition of the transistor Tr3.

As described in the first embodiment, when the alternating voltage is higher than the threshold voltage Vz, the photocoupler 404 is turned on, the transistor Tr3 is turned on, and the zero-cross signal ZEROX is at a low level. When the alternating voltage is lower than the threshold voltage Vz, the photocoupler 404 is turned off, the transistor Tr3 is also turned off, and the zero-cross signal ZEROX becomes the high level.

In this way, the level of the zero-cross signal ZEROX is switched according to whether the hot-side potential is higher than the neutral-side potential by the threshold voltage Vz or more. If the waveform of the alternating current is a sine wave, a zero-cross signal ZEROX is obtained that has an off-time that is wider than the off-time determined from the two true zero-cross points. In this case, the off-time of the zero-cross signal ZEROX here is Tsin2. The off-time may be referred to as an off-duty or an off-duty width.

As shown in FIG. 9B, the waveform of the alternating current supplied from the external power source 301 is a square wave. In this case, a zero-cross signal ZEROX (pulse waveform) having an off-time Tsquare2 equal to the interval between the two true zero-cross points is outputted to the CPU 131. The CPU 131 (waveform-detection unit 612) measures the off-time “toff” of the zero-cross signal ZEROX. When the off-time toff is less than Tsin2, the CPU 131 (determination unit 620) determines that the waveform of the alternating current is an abnormal waveform. When the off-time toff is not less than Tsin2, the CPU 131 (determination unit 620) determines that the waveform of the alternating current is a normal waveform.

As shown in FIG. 8, the output signal (zero-cross signal ZEROX) of the photocoupler 404 is output to the CPU 131 via the transistor Tr3. Therefore, when the potential generated by the output signal of the photocoupler 404 and the resistor R71 exceeds the base-emitter voltage of the transistor Tr3, the logical of the zero-cross signal ZEROX changes. Therefore, the responsiveness of the second embodiment is improved as compared with the first embodiment. That is, since the relationship indicated by the following equation Eq1 is satisfied, the detection accuracy of the normal waveform and the square wave (abnormal waveform) is improved.

(Tsin2−Tsquare2)>(Tsin1−Tsquare1) Eq1

As shown in FIG. 8, the Zener diode ZD substantially increases the threshold voltage Vz of the photocoupler 404. That is, the off-time Tsin2 when the sine wave is inputted is relatively increased. Accordingly, this further improves the detection accuracy of the square wave.

In the second embodiment, the waveform detection is not required to be performed in the step S705 and may be performed at other times. For example, it may be performed at regular measurement intervals in parallel with the processing shown in FIG. 7. The detection result of the waveform may be stored in a memory provided inside or outside the CPU 131, and may be read out as needed.

### Third Embodiment

The third embodiment is a modification of the first embodiment and the second embodiment. Specifically, when the abnormal waveform is detected when the heating end condition is satisfied, the rotation end condition of the pressure roller 208 is determined. For example, even if an abnormal waveform occurs, the pressure roller 208 may be stopped if the temperature of the heater 200 is normal. Alternatively, the pressure roller 208 may be stopped if the temperature of the heater 200 returns to normal within a predetermined time. Note that, when the abnormal waveform and the abnormal temperature continue even after a predetermined time has elapsed, the relay 302 may forcibly stop the supply of electric power to the heater 200. Description of matters common to the first embodiment and the second embodiment in the third embodiment will be omitted.

### 1. Flowchart

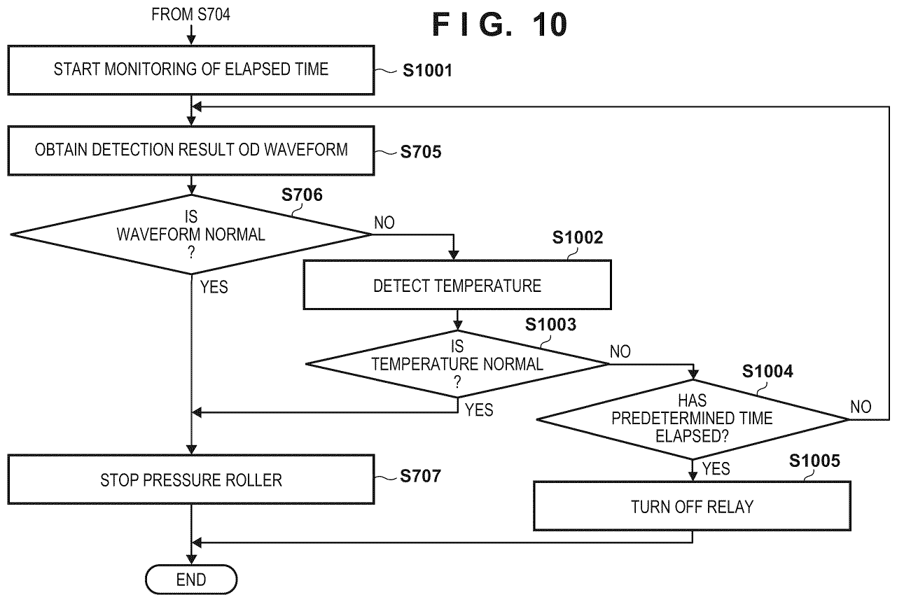

FIG. 10 shows a control method according to the third embodiment. Here, the process from the step S704 to the step S707 described in FIG. 7 is modified. The CPU 131 advances the process from the step S704 to the step S1001.

In the step S1001, the CPU 131 (time monitoring unit 614) starts monitoring the elapsed time using the timer 602. Here, the elapsed time is an elapsed time starting from a timing at which the supply of electric power to the heater 200 is stopped by turning off the triac 316. Note that the elapsed time may be a time period in which an abnormal waveform is continuously detected after the triac 316 is turned off. After that, the CPU 131 advances the process from the step S1001 to the step S705. In the step S705, the CPU 131 detects the waveform of the alternating current. When an abnormal waveform is detected in the step S706, the CPU 131 advances the process from the step S706 to the step S1002.

In the step S1002, the CPU 131 (temperature monitoring unit 611) uses the thermistor 211 to detect the temperature of the heater 200. In the step S1003, the CPU 131 (determination unit 620) determines whether the detected temperature of the heater 200 is normal. If the temperature of the heater 200 is normal, the CPU 131 advances the process from the step S1003 to the step S707 and stops the pressure roller 208. Since the supply of electric power to the heater 200 is stopped, the heater 200 dissipates heat naturally, and the temperature of the heater 200 gradually decreases. On the other hand, if the heater 200 is not normal, the CPU 131 advances the process from the step S1003 to the step S1004.

In the step S1004, the CPU 131 (determination unit 620) determines whether or not a predetermined time has elapsed based on the elapsed time acquired by the time monitoring unit 614. If the predetermined time has not yet elapsed, the CPU 131 advances the process from the step S1004 to the step S705. If the predetermined time has elapsed, the CPU 131 advances the process from the step S1004 to the step S1005.

In the step S1005, the CPU 131 (relay control unit 605) turns off the relay 302 (non-conductive state). Accordingly, the power supply to the heater 200 is forcibly stopped. Further, the CPU 131 deactivates the image forming apparatus 100. That is, the motor 118 is also stopped.

There are several schemes for determining the normality of temperature. The temperature monitoring unit 611 acquires the temperature T1 at the first timing using the thermistor 211, and acquires the temperature T2 at the second timing. The second timing is a timing later than the first timing by a predetermined time t1. Further, the temperature monitoring unit 611 calculates a difference ΔT between the temperature T1 and the temperature T2 (ΔT=T1−T2). If the temperature T2 is higher than the temperature T1, ΔT is a negative value. When the difference ΔT is equal to or lower than a threshold Tth1, the determination unit 620 determines that the temperature of the heater 200 is abnormal. The threshold Tth1 is a positive value equal to or greater than 0. When the difference ΔT exceeds the threshold Tth1, the determination unit 620 determines that the temperature of the heater 200 is normal. Note that, when ΔT is defined as ΔT=T2−T1, the magnitude relation between the difference ΔT and the threshold Tth1 is logically inverted.

Alternatively, the temperature monitoring unit 611 may obtain a temperature gradient G of the heater 200 by dividing the difference ΔT by a predetermined time t1. The determination unit 620 determines whether or not the temperature gradient G is equal to or lower than a gradient threshold Gth. If the temperature gradient G is equal to or lower than the gradient threshold Gth, it is determined that the temperature of the heater 200 is normal. If the temperature gradient G exceeds the gradient threshold Gth, it is determined that the temperature of the heater 200 is abnormal. The gradient threshold Gth is a positive value equal to or greater than 0. Note that, when ΔT is defined as ΔT=T2−T1, the magnitude relation between the temperature gradient G and the gradient threshold Gth is logically inverted.

Alternatively, if the temperature T2 is equal to or lower than a temperature threshold Tth2, it may be determined that the temperature of the heater 200 is normal. If the temperature T2 exceeds a temperature threshold Tth2, it is determined that the temperature of the heater 200 is abnormal. The threshold Tth2 is a positive value equal to or greater than 0.

In the third embodiment, as in the first embodiment and the second embodiment, in the rotation continuation period, the rotation speed of the pressure roller 208 may be any speed at which failure of the heating device 113 can be suppressed. The rotation speed applied during the rotation continuation period may be different from the rotation speed during the heating process.

In the first embodiment and the second embodiment, when the temperature of the heater 200 becomes abnormal during the rotation continuation period, the thermostat 212 is finally turned from the conductive state to the non-conductive state, whereby the image forming apparatus 100 is stopped. Alternatively, the relay 302 transitions from the conductive state to the non-conductive state before the thermostat 212 transitions from the conductive state to the non-conductive state. In the first embodiment and the second embodiment, the driving of the pressurizing device 114 is continued while the waveform of the alternating current is abnormal. That is, the image forming apparatus 100 cannot perform a print operation.

The third embodiment is useful when the triac 316 is not fixed ON even if an abnormal waveform is detected. That is, in the third embodiment, even if the abnormal waveform is detected, if the temperature of the heater 200 is normal, the pressure roller 208 is immediately stopped. That is, the image forming apparatus 100 can execute the following print job, and the productivity of the image forming apparatus 100 is less likely to decrease.

In the third embodiment, the waveform detection is not required to be performed in the step S705 and may be performed at other times. For example, it may be performed at regular measurement intervals in parallel with the processing shown in FIG. 7. The detection result of the waveform may be stored in a memory provided inside or outside the CPU 131, and may be read out as needed.

### Fourth Embodiment

The fourth embodiment is a modification of the first embodiment or the third embodiment. When the abnormal waveform is detected, the relay 302 is maintained in the cutoff state for at least a predetermined period of time. Thereafter, the pressure roller 208 is stopped. Description of matters common to the first embodiment, the second embodiment, or the third embodiment in the fourth embodiment will be omitted.

### 1. Flowchart

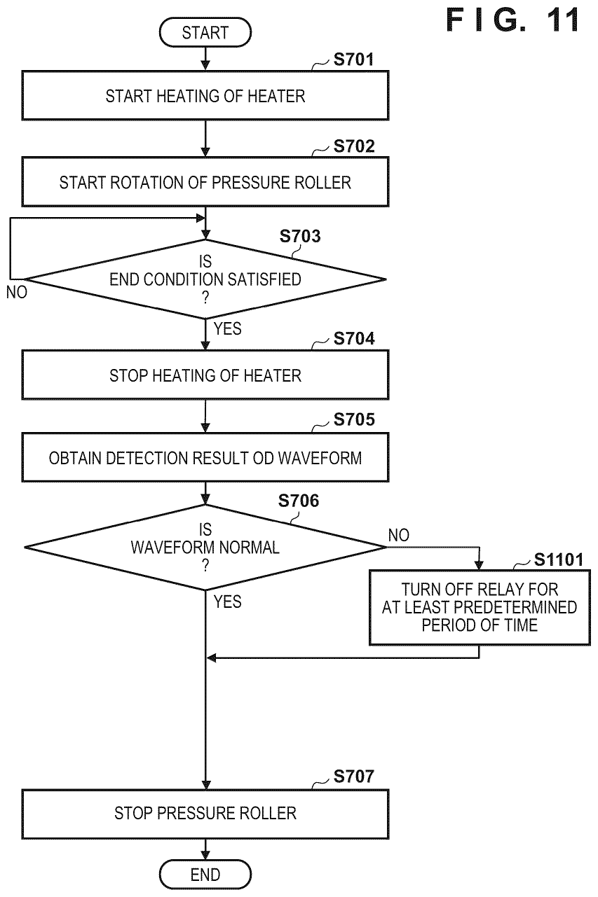

FIG. 11 shows a control method according to the fourth embodiment. When an abnormal waveform is detected in the step S706, the pressure roller 208 continues to rotate. That is, the stop of the pressure roller 208 is postponed, and the rotation continuation time (driving time) is extended. Further, the CPU 131 advances the process from the step S706 to the step S1101.

In the step S1101, the CPU 131 (relay control unit 605) turns off the relay 302 for at least a predetermined time (non-conductive state). Accordingly, the power supply to the heater 200 is stopped. For example, the predetermined time may be equal to or more than a half cycle of the alternating current. By stopping the supply of power to the heater 200 for at least the half cycle, the square wave is cut beyond the zero-cross point to more reliably switch the triac 316 from ON to OFF. Therefore, even if a malfunction of the triac 316 occurs due to an abnormal waveform such as a square wave, the image forming apparatus 100 is safely stopped.

As shown in FIG. 3, since the relay 302 is disposed between the external power source 301 and the detection circuit 308, the detection circuit 308 cannot detect an abnormal waveform when the relay 302 is turned off. However, since the off period of the relay 302 is equal to or more than the half cycle of the alternating current, the period in which the detection circuit 308 cannot execute the waveform detection is short.

In the fourth embodiment, the pressure roller 208 is stopped after the relay 302 is turned off for at least a predetermined period of time, but this is merely an example. That is, the first period, which is the rotation continuation period (driving time) of the pressure roller 208, may be longer than the second period in which the relay 302 is maintained OFF. In this case, the time monitoring unit 614 monitors both the first period and the second period using the timer 602. The starting point of the first period and the starting point of the second period are, for example, timings at which the heating of the heater 200 is stopped by the step S704 or timings at which an abnormal waveform is detected by the step S706. Note that a timing at which an abnormal temperature is detected may be adopted as the starting point. As described in the first embodiment or the like, the rotation speed of the pressure roller 208 in the first period may be a rotation speed at which failure of the heating film 202 can be suppressed. Further, the timing at which the relay 302 returns from the non-conductive state (OFF) to the conductive state (ON) may be after the pressure roller 208 stops.

In the fourth embodiment, the malfunction of the triac 316 caused by the abnormal waveform can be cancelled in a shorter time than in the first embodiment to third embodiment. Therefore, the time during which the rotation of the pressure roller 208 is continued can also be reduced. Therefore, the lifetime of the fixing device can be extended, and the power consumed by the image forming apparatus 100 can be reduced.

In the fourth embodiment, the waveform detection is not required to be performed in the step S705 and may be performed at other times. For example, it may be performed at regular measurement intervals in parallel with the processing shown in FIG. 7. The detection result of the waveform may be stored in a memory provided inside or outside the CPU 131, and may be read out as needed.

### Fifth Embodiment

The fifth embodiment is a modification of the first embodiment or the like. In the first embodiment to fourth embodiment, at least an abnormal waveform of an alternating current is detected, but this is merely an example. For example, in a case where the temperature of the heater 200 is abnormal in the stop postponement period of the pressure roller 208, the relay 302 may be turned off for a predetermined period of time described in the fourth embodiment. Note that the zero-cross signal ZEROX detected by the detection circuit 308 may be used by the power failure detection unit 613 to detect a power failure of the external power source 301.

### 1. Power Failure Detection

The memory 601 may include a large-capacity, non-volatile storage device (e.g., HDD, SSD). A RAM area of the memory 601 can temporarily store printing image data transmitted from a host computer or the like. When the memory 601 stores the printing image data in the HDD of the memory 601, the external power source 301 may fail or the power cable connecting the external power source 301 and the image forming apparatus 100 may be disconnected from the outlet. Accordingly, when the power cutoff occurs, the power that can be supplied from a spare power source provided inside the image forming apparatus 100 gradually decreases. As a consequence, data corruption or data inconsistency occurs in the HDD, and the CPU 131 cannot read data from the HDD.

Therefore, the power failure detection unit 613 detects a power failure and an unintended cutoff of power based on the zero-cross signal ZEROX. The CPU 131 saves the printing image data from the RAM to the HDD from the moment when the power failure occurred until the image forming apparatus 100 is completely stopped. Accordingly, the data is protected. For example, the power failure detection unit 613 determines that the external power source 301 has failed when the zero-cross signal ZEROX is not input for a predetermined time or longer. The power failure detection unit 613 may measure an elapsed time “tp” from the edge of the zero-cross signal ZEROX using the timer 602, and determine whether or not the elapsed time tp exceeds a threshold time “tth”. When the elapsed time tp exceeds the threshold time tth, the power failure detection unit 613 determines that a power failure has occurred. When the elapsed time tp does not exceed the threshold time tth, the power failure detection unit 613 determines that a power failure is not occurred.

The detection circuit 308 outputs a zero-cross signal ZEROX whenever an alternating current is supplied from the external power source 301. Therefore, the power failure detection unit 613 constantly consumes power. Since the detection circuit 308 is connected between the relay 302 and the triac 316, the power consumption of the power failure detection unit 613 is reduced when the relay 302 is turned off.

### 2. Flowchart

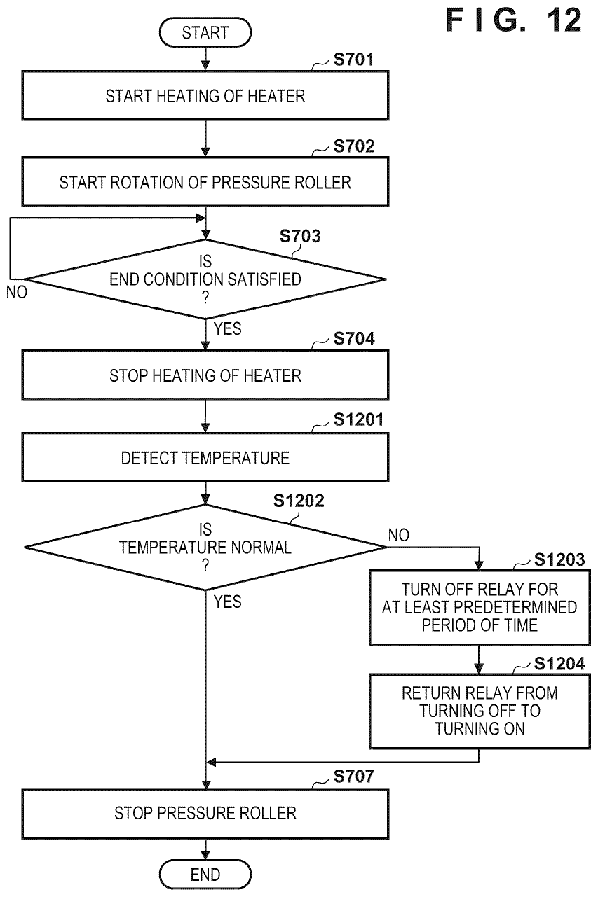

FIG. 12 shows a control method according to the fifth embodiment. The step S705 and the step S706 described in FIG. 7 have been replaced from the step S1201 to the step S1204. Therefore, the step S1201 to the step S1204 will be mainly described below. When the heating of the heater 200 is stopped in the step S704, the CPU 131 advances the process from the step S704 to the step S1201.

In the step S1201, the CPU 131 (temperature monitoring unit 611) uses the thermistor 211 to detect the temperature of the heater 200. In the step S1202, the CPU 131 (determination unit 620) determines whether the detected temperature of the heater 200 is normal. The determination of the normality is the same as the determination of the step S1003. If the temperature of the heater 200 is normal, the CPU 131 advances the process from the step S1202 to the step S707. Accordingly, the pressure roller 208 is stopped. On the other hand, when the temperature of the heater 200 is not normal even though the triac 316 is turned off, the CPU 131 advances the process from the step S1202 to the step S1203.

In the step S1203, the CPU 131 (relay control unit 605) turns off the relay 302 for at least a predetermined period of time. Accordingly, the power supply to the heater 200 is forcibly stopped. The step S1203 is the same process as the step S1101, and the predetermined period of time may be equal to or more than the half cycle of the alternating current. For example, the CPU 131 (time monitoring unit 614) may monitor a predetermined period of time using the timer 602.

In the step S1204, the CPU 131 (relay control unit 605) returns the relay 302 from turning off (non-conductive state) to turning on (conductive state). After that, the CPU 131 advances the process from the step S1204 to the step S707. Accordingly, the motor 118 is stopped.

As shown in FIG. 3, since the relay 302 is disposed between the external power source 301 and the detection circuit 308, the detection circuit 308 cannot detect the zero-cross signal ZEROX when the relay 302 is turned off. However, since the off period of the relay 302 is equal to or more than the half cycle of the alternating current, the period in which the detection circuit 308 cannot execute the detection of the zero-cross signal ZEROX is short. That is, the period in which the power failure detection unit 613 cannot perform the power failure detection is also shortened.

In the fifth embodiment, the pressure roller 208 is stopped after the relay 302 is turned off for at least a predetermined period of time, but this is merely an example. That is, the first period, which is the rotation continuation period of the pressure roller 208, may be longer than the second period in which the relay 302 is maintained OFF. In this case, the time monitoring unit 614 monitors both the first period and the second period using the timer 602. The starting point of the first period and the starting point of the second period are, for example, timings at which the heating of the heater 200 is stopped by the step S704 or timings at which an abnormal temperature is detected by the step S1202. As described in the first embodiment or the like, the rotation speed of the pressure roller 208 in the first period may be any rotation speed at which failure of the heating film 202 can be suppressed. Further, the timing at which the relay 302 returns from the non-conductive state (OFF) to the conductive state (ON) may be after the pressure roller 208 stops.

In the fifth embodiment, when the temperature of the heater 200 becomes an abnormal temperature due to an abnormal waveform of the alternating current or the like, the relay 302 cuts off the supply of electric power to the heater 200. That is, the CPU 131 can estimate the occurrence of an abnormal waveform causing an abnormal temperature increase without directly detecting the waveform of the alternating current. When the CPU 131 detects an abnormal temperature increase, it turns off the relay 302 for a predetermined period of time, thereby suppressing the failure of the heating device 113 and the pressurizing device 114. The period during which the supply of power is forcibly cutoff by the relay 302 is merely at least a half cycle of the alternating current. Therefore, the period in which the power failure detection unit 613 cannot perform the power failure detection is also shortened. Further, the time during which the rotation of the pressure roller 208 is continued can also be reduced. Therefore, the lifetime of the fixing device 190 can be extended, and the power consumed by the image forming apparatus 100 can be reduced.

In the fifth embodiment, the waveform detection is not required to be performed in the step S705 and may be performed at other times. For example, it may be performed at regular measurement intervals in parallel with the processing shown in FIG. 7. The detection result of the waveform may be stored in a memory provided inside or outside the CPU 131, and may be read out as needed.

### Technical Ideas Derived from the Embodiments

The motor 118 is an example of a driving unit and driving unit. The pressure roller 208 is an example of a first rotating body. The heating film 202 is an example of a second rotating body. The heater 200 is an example of a heater. The triac 316 and CPU 131 are examples of a switching unit and switching circuit. The relay 302 is an example of a cutoff unit or cutoff circuit. The detection circuit 308 and the CPU 131 are examples of a waveform detecting unit and waveform detecting circuit. In this way, according to the present embodiment, the motor 118 is stopped by being delayed with respect to the heater 200. Accordingly, the temperature difference between the fixing nip portion N and its surroundings is reduced, and the image forming apparatus 100 can be appropriately protected from heat.

If an abnormal waveform occurs, the triac 316 may malfunction and the heater 200 may generate heat. While the occurrence of the abnormal waveform continues, the motor 118 will continue to rotate, thereby suppressing an abnormal temperature increase of the heater 200 and the heating film 202. Accordingly, this adequately protects the image forming apparatus 100 (in particular the fixing device 190) from heat.

The thermistor 211 and the CPU 131 are examples of a temperature monitoring unit and temperature monitoring circuit. The CPU 131 is an example of a determination unit and determining circuit. As shown in FIG. 10, when the abnormal waveform and the abnormal temperature occur at the same time, the motor 118 may continue the rotation of the pressure roller 208. Accordingly, this adequately protects the image forming apparatus 100 from heat. Further, even if an abnormal waveform occurs, the motor 118 may be stopped immediately if the temperature of the heater 200 is normal. Accordingly, this reduces the amount of time that the image forming apparatus 100 is unable to perform printing, and makes it difficult to decrease the productivity of the image forming apparatus 100.

As described with reference to FIG. 10, the starting point of the first period (predetermined time) may be any of these three timings. The first period may be referred to as a rotation continuation period, a rotation extension period, or a stop postponement period. When the relay 302 cuts off the power supply path in the step S1005, the power supply to the motor 118 may also be cut off. Alternatively, the motor 118 may be supplied the power from a direct current power source that is not affected by the conduction/cutoff of the relay 302. In this case, the CPU 131 stops the motor 118 through the motor control unit 604. Accordingly, the motor 118 can be stopped.

In this way, when the temperature returns to normal, the motor 118 may be stopped. The amount of time that the image forming apparatus 100 is unable to perform printing is further reduced, and this makes it difficult to decrease the productivity of the image forming apparatus 100.

As described in connection with the step S1005, the abnormal waveform and the abnormal temperature may continue even after a predetermined time has elapsed. In this case, the relay 302 may forcibly cut off the power supply path to the heater 200. After that, the CPU 131 may stop the motor 118.

As illustrated in FIG. 11, when the abnormal waveform is detected when the heating end condition is satisfied, the supply of electric power to the heater 200 may be stopped by the relay 302 for a predetermined period of time.

As described in connection with FIG. 11, the relay 302 is in the cutoff state for a predetermined period of time, but may then return to the conductive state. Further, the motor 118 may stop after the relay 302 returns to the conductive state. Accordingly, this would allow both heat protection of the image forming apparatus 100 and maintenance of the productivity of the image forming apparatus 100.

The half cycle of the alternating current may be measured through the detection circuit 308 or may be a nominal half cycle. Accordingly, this may reduce the amount of time in which the image forming apparatus 100 is unable to form images.

As described in the third embodiment, the normality of the temperature may be determined based on the temperatures T1 and T2.

As described in the third embodiment, the normality of the temperature may be determined based on the temperature difference between the temperatures T1 and T2.

As described in the third embodiment, the normality of the temperature may be determined based on the temperature gradient (e.g., G) and the gradient threshold (e.g., Gth).

As described in the third embodiment, the normality of the temperature may be determined based on the temperature T2.

The detection circuit 308 is an example of a circuit that outputs a zero-cross waveform.

As described in the first embodiment or the like, the CPU 131 may detect an abnormal waveform based on the zero-cross signal ZEROX.

As described in the first embodiment or the like, the CPU 131 may detect an abnormal waveform based on an on-time (on-duty) or an off-time (off-duty) of the zero-cross signal ZEROX.

The detection circuit 308 prepared for power failure detection may be used to detect an abnormal waveform of the alternating current.

The detection circuit 308 employed for power control of the heater 200 may be used to detect an abnormal waveform of the alternating current.

As described in the first embodiment, the zero-cross signal ZEROX may be outputted from the light receiving elements of the photocoupler 404. As described in the second embodiment, the zero-cross signal ZEROX may be outputted through the phototransistor Tr3. In particular, in the second embodiment, the responsiveness of the zero-cross signal ZEROX is improved.

The Zener diode ZD is an example of a constant voltage element. By employing the constant voltage element, the threshold voltage Vz for the light emitting element of the photocoupler 404 to emit light is increased. Accordingly, it is easy to distinguish between the abnormal waveform and the normal waveform.

The detection circuit 308 may be disposed between the relay 302 and the external power source 301. However, in this case, the detection circuit 308 consumes power at all times. As shown in FIG. 3, the detection circuit 308 may be disposed between the relay 302 and the heater 200. In this case, when the relay 302 is turned off, the detection circuit 308 is stopped, so that the power consumption of the detection circuit 308 is reduced.

The motor 118 may drive the pressure roller 208 so that the heating film 202 and the pressure roller 208 rotate at a rotation speed at which they are not stuck. However, the rotation speed may be lower than the rotation speed at the time of image formation. The relay 302 may be an electromagnetic relay. The triac 316 may be another type of a semiconductor switch. The heater 200 may be a ceramic heater or a halogen lamp.

The pressure roller 208 and the process cartridge 109 for supplying toner may be driven by the same driving source. Accordingly, the number of driving sources may be reduced.

As described in the fifth embodiment, monitoring or detection of an abnormal waveform is not essential. When the heating end condition is satisfied and the abnormal temperature is detected, the relay 302 may be turned off for a predetermined period of time. After that, the relay 302 returns to ON, and the motor 118 may stop.

The CPU 131 is an example of a control unit and controlling circuit. Delaying the stop timing of the motor 118 from the stop timing of the heater 200 corresponds to continuing the rotation of the motor 118.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-123432, filed Jul. 30, 2024 which is hereby incorporated by reference herein in its entirety.

What is claimed is:

1. An image forming apparatus comprising:
a first rotating body driven by a motor and configured to rotate;
a second rotating body disposed opposite to the first rotating body and configured to cooperate with the first rotating body to form a nip portion;
a heater configured to heat the second rotating body by being supplied with an alternating current from an external power source;
a switch disposed between the external power source and the heater, and configured to adjust power supplied to the heater so that a temperature of the heater approaches a target temperature;
a cutoff element connected in series with the switch between the external power source and the heater and configured to cut off an alternating current supplied from the external power source to the heater; and
a waveform sensor configured to detect an abnormal waveform of the alternating current,
wherein, in a case where an end condition where the heating of the heater is ended is satisfied, the switch stops supplying of the power to the heater,
in a case where the abnormal waveform is not detected when the end condition is satisfied, the motor is stopped, and
in a case where the abnormal waveform is detected when the end condition is satisfied, the motor is stopped after being delayed from the heater.

2. The image forming apparatus according to claim 1, wherein, when the waveform of the alternating current returns from the abnormal waveform to a normal waveform, the motor is stopped.

3. The image forming apparatus according to claim 1, further comprising:
a temperature sensor configured to monitor a temperature of the heater; and
a determination circuit configured to determine whether the temperature is normal in a case where the abnormal waveform is detected when the end condition is satisfied,
wherein when the temperature is normal, the motor is stopped, and
when the temperature is not normal, the motor continues to operate further.

4. The image forming apparatus according to claim 3, wherein, when a first period of time elapses from a timing at which the end condition is satisfied, a timing at which the abnormal waveform is detected, or a timing at which it is detected that the temperature is not normal, the motor is stopped.

5. The image forming apparatus according to claim 1, wherein, when the temperature returns to a normal before the first period of time has elapsed, the motor is stopped.

6. The image forming apparatus according to claim 4, wherein in a case where the abnormal waveform is detected and the temperature is not normal even when the first period of time has elapsed, the motor is stopped after the cutoff element forcibly cuts off the heater from the external power source.

7. The image forming apparatus according to claim 1, wherein in a case where the abnormal waveform is detected when the end condition is satisfied, the cutoff element forcibly cuts off the heater from the external power source for a second period of time, and the motor is stopped when the second period of time ends.

8. The image forming apparatus according to claim 1, wherein in a case where the abnormal waveform is detected when the end condition is satisfied, the cutoff element forcibly cuts off the heater from the external power source for a second period of time, and the cutoff element returns from a cutoff state to a conductive state and the motor is stopped when the second period of time ends.

9. The image forming apparatus according to claim 7, wherein the second period of time is a period of time equal to or more than a half cycle of the alternating current.

10. The image forming apparatus according to claim 3, wherein the determination circuit acquires a first temperature that is a temperature of the heater at a first timing, acquires a second temperature that is a temperature of the heater at a second timing after the first timing, and determines whether the temperature of the heater is normal based on the first temperature and the second temperature.

11. The image forming apparatus according to claim 10, wherein the determination circuit determines whether the temperature of the heater is normal based on a temperature threshold and a difference between the first temperature and the second temperature.

12. The image forming apparatus according to claim 10, wherein the determination circuit determines whether the temperature of the heater is normal based on a gradient threshold and a temperature gradient between the first temperature and the second temperature.

13. The image forming apparatus according to claim 3, wherein the determination circuit determines whether the temperature of the heater is normal based on a threshold temperature and the temperature.

14. The image forming apparatus according to claim 1, further comprising a detection circuit configured to output a pulse waveform repeating rising and falling in response to zero-cross of the alternating current.

15. The image forming apparatus according to claim 14, wherein the waveform sensor is configured to detect the abnormal waveform based on the pulse waveform.

16. The image forming apparatus according to claim 15, wherein the waveform sensor is configured to detect the abnormal waveform based on an on-time or an off-time of the pulse waveform.

17. The image forming apparatus according to claim 14, further comprising a power failure detection circuit configured to detect a power failure of the external power source based on of the pulse waveform.

18. The image forming apparatus according to claim 14, further comprising a controller configured to control the power supplied to the heater relative to of the pulse waveform.

19. An image forming apparatus comprising:
a first rotating body driven by a motor and configured to rotate;
a second rotating body disposed opposite to the first rotating body and configured to cooperate with the first rotating body to form a nip portion;
a heater configured to heat the second rotating body by being supplied with an alternating current from an external power source;
a switch disposed between the external power source and the heater, and configured to adjust power supplied to the heater so that a temperature of the heater approaches a target temperature;
a cutoff element connected in series with the switch between the external power source and the heater and configured to cut off an alternating current supplied from the external power source to the heater; and
at least one processor arranged between the cutoff element and the switch and configured to detect a power failure of the external power source, and monitor a temperature of the heater,
wherein, in a case where an end condition where the heating of the heater is ended is satisfied, the switch stops supplying of the power to the heater,
in a case where it is not detected that temperature of the heater is abnormal when the end condition is satisfied, the motor is stopped, and
in a case where it is detected that the temperature of the heater is abnormal when the end condition is satisfied, the power supplied from the external power source to the heater is cut off by the cutoff element for at least a predetermined period of time, and the motor is stopped after being delayed from the heater.

20. The image forming apparatus according to claim 19, wherein the predetermined period of time is a half cycle of the alternating current.

21. The image forming apparatus according to claim 19, wherein the at least one processor is further configured to detect that the external power source fails in a case where a pulse waveform in which a rising edge and a falling edge are repeated in response to the zero-cross of the alternating current cannot be detected for a prescribed time.

22. The image forming apparatus according to claim 19, further comprising a photocoupler including a light emitting element configured to repeat turning on and off in response to the alternating current supplied from the external power source and a light receiving element configured to generate a pulse waveform by receiving light outputted from the light emitting element,
wherein the at least one processor is further configured to detect a power failure of the external power source using the pulse waveform outputted from the photocoupler.

23. The image forming apparatus according to claim 19, wherein the at least one processor is further configured to acquire a first temperature which is a temperature of the heater at a first timing, and acquire a second temperature which is a temperature of the heater at a second timing after the first timing, and determine whether the temperature of the heater is abnormal based on the first temperature and the second temperature.

24. The image forming apparatus according to claim 23, wherein the at least one processor is further configured to determine whether the temperature of the heater is abnormal based on a temperature threshold and a difference between the first temperature and the second temperature.

25. The image forming apparatus according to claim 23, wherein the at least one processor is further configured to determine whether the temperature of the heater is abnormal based on a gradient threshold and a temperature gradient between the first temperature and the second temperature.

26. The image forming apparatus according to claim 19, wherein the at least one processor is further configured to determine whether the temperature of the heater is normal based on a threshold temperature and the temperature.

27. The image forming apparatus according to claim 20, wherein a driving time of the motor is extended such that the motor is stopped after the power supplied from the external power source to the heater is cut off by the cutoff element for at least a half cycle of the alternating current.

28. An image forming apparatus comprising:
a first rotating body driven by a motor and configured to rotate;
a second rotating body disposed opposite to the first rotating body and configured to cooperate with the first rotating body to form a nip portion;
a heater configured to heat the second rotating body by being supplied with an alternating current from an external power source;
a switch disposed between the external power source and the heater, and configured to adjust power supplied to the heater so that a temperature of the heater approaches a target temperature;
a cutoff element connected in series with the switch between the external power source and the heater and configured to cut off an alternating current supplied from the external power source to the heater; and
a waveform sensor configured to detect an abnormal waveform of the alternating current,
a controller configured to control the motor, the switch, and the cutoff element,
wherein the controller is further configured to:
control the switch to stop the supply of power to the heater when an end condition for ending the heating of the heater is satisfied,
control the motor to stop in a case where the abnormal waveform is not detected when the end condition is satisfied, and
delay a stop timing of the motor from a stop timing of the heater in a case where the abnormal waveform is detected when the end condition is satisfied.
